(19) United States
(12) Patent Application Publication
(10) Pub. No.: US 2010/0001389 A1
(43) Pub. Date: Jan. 7, 2010

(54) PACKAGE STRUCTURE FOR RADIO FREQUENCY MODULE AND MANUFACTURING METHOD THEREOF

(76) Inventor: Jian-Cheng CHEN, Siaying Township (TW)

Correspondence Address: Muncy, Geissler, Olds & Lowe, PLLC, P.O. BOX 1364, FAIRFAX, VA, 22038-1364, US

(21) Appl. No.: 12/478,434

(22) Filed: Jun. 4, 2009

(30) Foreign Application Priority Data
Jul. 7, 2008 (TW) 97125555

(51) Int. Cl. H01L 23/498; H01L 21/50

(52) U.S. Cl. 257/685; 438/107; 257/E21.499; 257/E23.068

(57) ABSTRACT

A package structure for radio frequency module and a manufacturing method thereof are provided. The package structure includes a multi-layer substrate, a first chip, a second chip, a number of solder bumps, a first molding compound and a second molding compound. The substrate includes a metallic middle layer and has a first and a second surfaces. The first and the second chips respectively disposed on the first and the second surfaces are electrically connected to the substrate. The first molding compound is disposed on the first surface and covers the first chip. The solder bumps disposed on the second surface are respectively electrically connected to the first and the second chips via the substrate. The second molding compound disposed on the second surface covers the second chip and encircles the sidewalls of the solder bumps, and the connection surfaces of solder bumps are exposed outside the second molding compound.

This application claims the benefit of Taiwan application Serial No. 97125555, filed Jul. 7, 2008, the subject matter of which is incorporated herein by reference.

### BACKGROUND OF THE INVENTION

1. Field of the Invention

The invention relates in general to a package structure and a manufacturing method thereof, and more particularly to a package structure for radio frequency module and the manufacturing method thereof.

2. Description of the Related Art

Normally, the radio frequency module includes a radio frequency element and a base band element. Conventionally, a side by side multi-chip module (MCM) package is used to avoid the interference between the radio frequency element and the base band element. However, the MCM package is disadvantaged in that the module area is too large and the products using the bulky side by side MCM packages are lacking of market competitiveness. In addition to the side by side structure, conventional structure also packages the radio frequency element and the base band element in a die stacked structure. Referring to FIG. 1, a cross-sectional view of a conventional die stacked package for radio frequency module is shown. As indicated in FIG. 1, the package structure for radio frequency module 100 adopting a die stacked structure has a metallic cover 115 disposed between the chips 110 and 120 to cause an electromagnetic shielding effect and avoid the interference between the chips 110 and 120. However, such package structure is disadvantaged in that the module is too thick and that the disposition of the metallic cover incurs extra cost and requires more complicated manufacturing process, hence making the product using such package structure lack of market competitiveness.

### SUMMARY OF THE INVENTION

The invention is directed to a package structure for radio frequency module and the manufacturing method thereof. A base band element and a radio frequency element are respectively disposed on a first surface and a second surface of a multi-layer substrate, wherein the multi-layer substrate at least has a metallic middle layer to achieve electromagnetic shielding effect. Besides, the connection surfaces of the solder bumps are exposed outside the second molding compound, such that the package structure can be connected to the solder bumps via an I/O frame board and further electrically connected to an external circuit. The package structure of the invention is advantaged in that the module is thinned and is easy to be customized, hence increasing the market value of the product.

According to a first aspect of the present invention, a method for manufacturing a package structure for radio frequency module is provided. The manufacturing method includes the following steps. Firstly, a multi-layer substrate is provided, wherein the substrate includes a metallic middle layer and has a first surface and a second surface opposite to each other. Next, a first chip is disposed on the first surface, such that the first chip is electrically connected to the substrate. Then, a first molding compound is formed on the first surface to cover the first chip. After that, a second chip is disposed on the second surface, such that the second chip is electrically connected to the substrate. Afterwards, a number of solder bumps are disposed on the second surface, such that the solder bumps are respectively electrically connected to the first chip and the second chip via the substrate. Then, a molding compound is formed on the second surface to cover the second chip and the solder bumps. Finally, a part of the molding compound is cut to form a second molding compound which covers the second chip, and the connection surfaces of the solder bumps are exposed outside the second molding compound.

According to a second aspect of the present invention, a package structure for radio frequency module is provided. The package structure includes a multi-layer substrate, a first chip, a second chip, a number of solder bumps, a first molding compound and a second molding compound. The substrate includes a metallic middle layer and has a first surface and a second surface opposite to each other. The first and the second chip are respectively disposed on the first surface and the second surface and electrically connected to the substrate. The first molding compound is disposed on the first surface and covers the first chip. The solder bumps are disposed on the second surface and respectively electrically connected to the first and the second chip via the substrate. The second molding compound is disposed on the second surface. The second molding compound covers the second chip and encircles the sidewalls of the solder bumps, and the connection surfaces of the solder bumps are exposed outside the second molding compound.

The invention will become apparent from the following detailed description of the preferred but non-limiting embodiments. The following description is made with reference to the accompanying drawings.

### BRIEF DESCRIPTION OF THE DRAWINGS

FIG. 1 shows a cross-sectional view of a conventional die stacked package for radio frequency module; and

FIGS. 2A˜2J respectively show the steps of a method for manufacturing a package structure for radio frequency module according to a preferred embodiment of the invention.

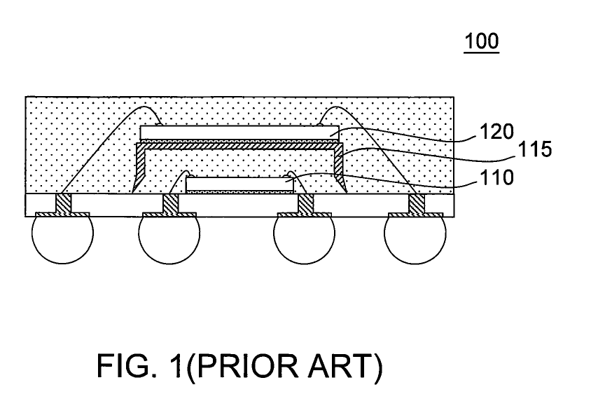

### DETAILED DESCRIPTION OF THE INVENTION

The invention discloses a package structure for radio frequency module and a manufacturing method thereof. A base band element and a radio frequency element are respectively disposed on a first surface and a second surface of a multi-layer substrate, wherein the multi-layer substrate at least has a metallic middle layer to achieve an electromagnetic shielding effect. Besides, the manufacturing method includes a partly cut step, such that the connection surfaces of the solder bumps are exposed outside the second molding compound. An I/O frame board is electrically connected to the solder bumps, such that the package structure is electrically connected to an external circuit via the I/O frame board. The package structure of the invention is advantaged in that the module is thinned and is easy to be customized, hence increasing the market value of the product.

A preferred embodiment is disclosed below with accompanied drawings. However, the package structure for radio frequency module disclosed in the preferred embodiment and the manufacturing method thereof are for exemplification purpose not for limiting the scope of protection of the invention. Thus, the specification and the drawings are to be regard as an illustrative sense rather than a restrictive sense. Additionally, the drawings used for illustrating the embodiments and applications of the present invention only show the major characteristic parts in order to avoid obscuring the present invention.

### <Manufacturing Method of Package Structure for Radio Frequency Module>

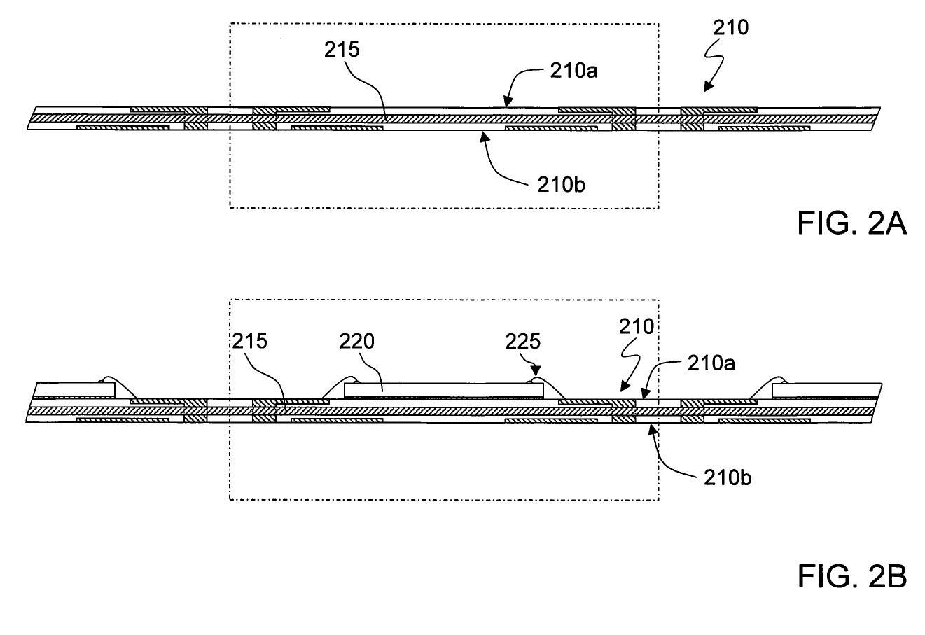

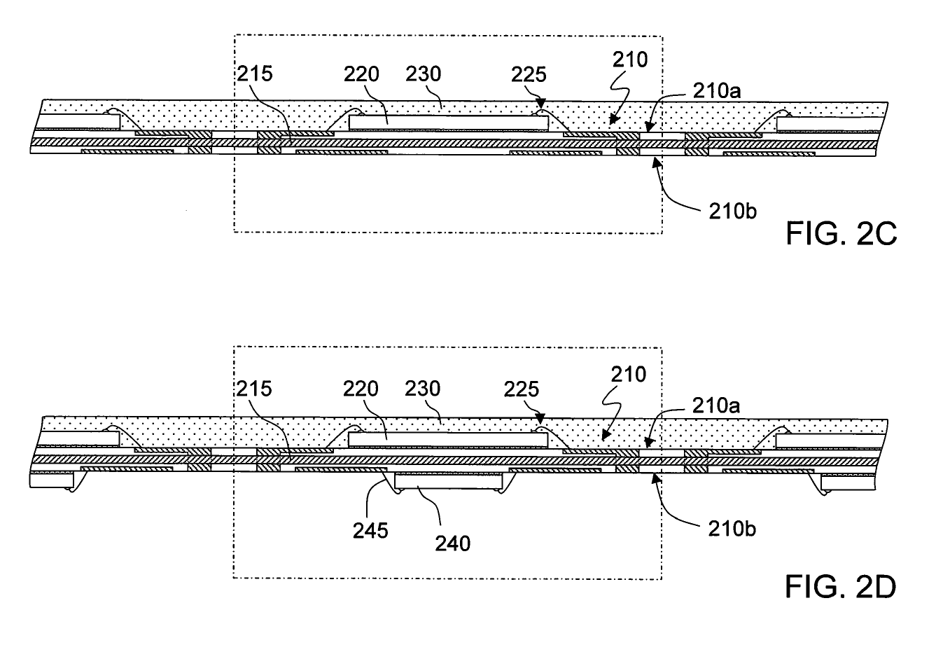

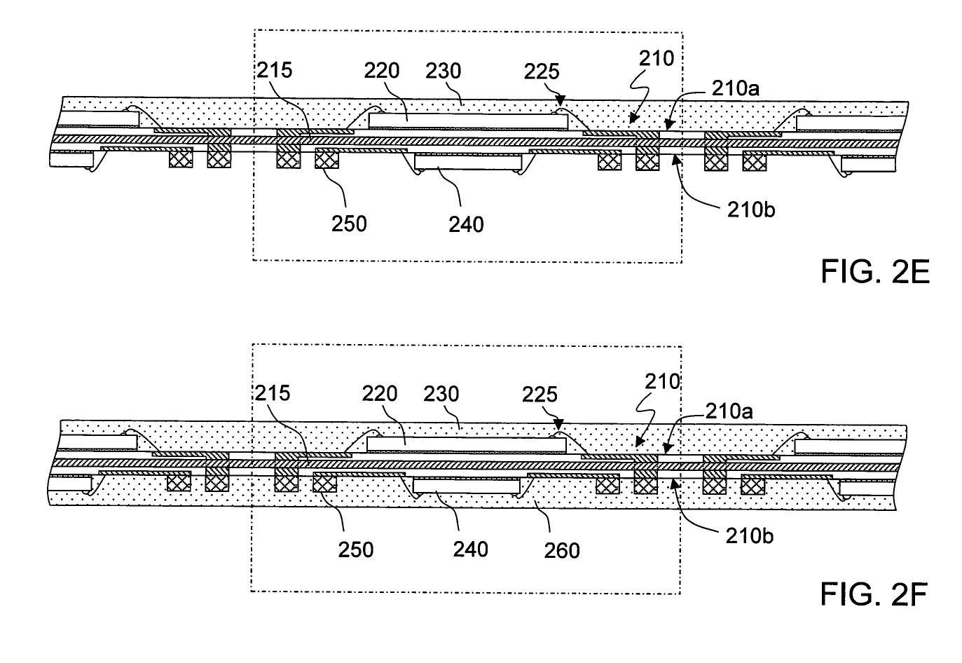

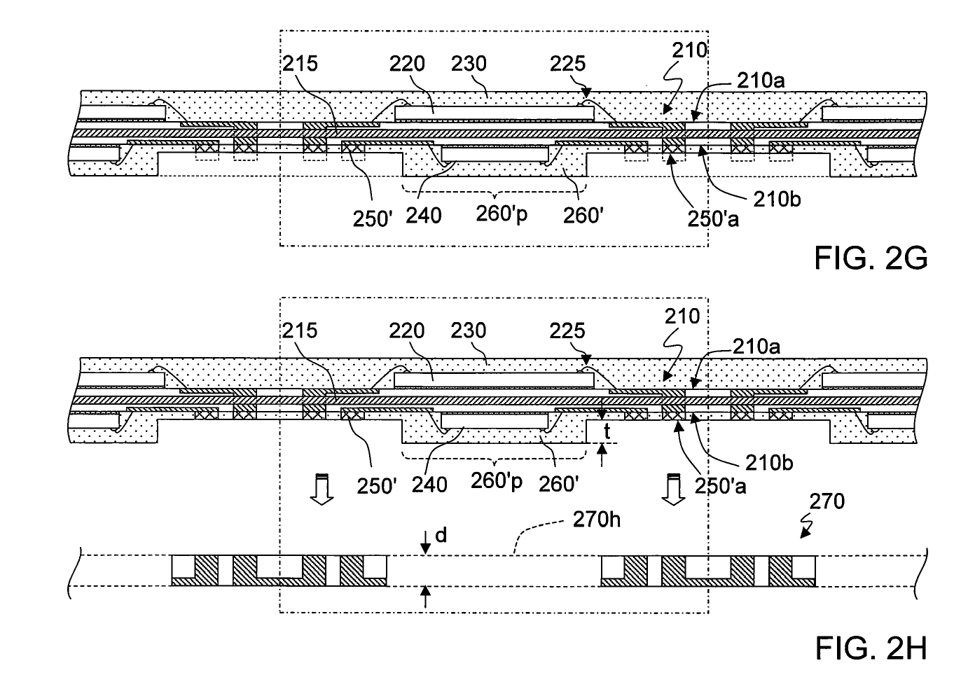

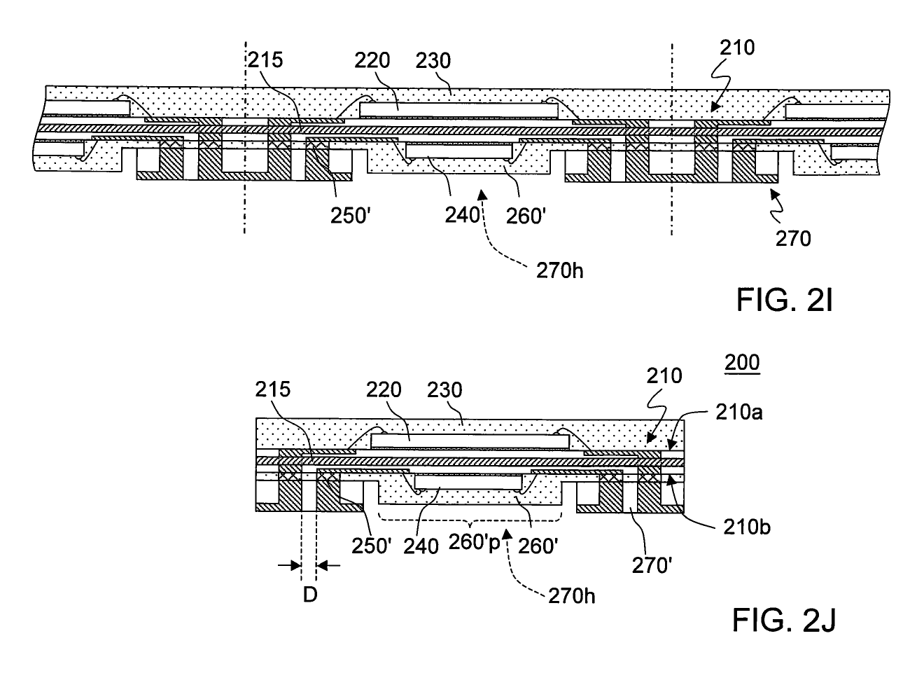

A package structure for radio frequency module according to a preferred embodiment of the invention is disclosed below as a reference for the implementation of the technology of the invention. Also, secondary elements are omitted in the embodiment for highlighting the technical features of the invention. Referring to FIGS. 2A˜2J, steps of a method for manufacturing a package structure for radio frequency module according to a preferred embodiment of the invention are illustrated.

Firstly, as indicated in FIG. 2A, a multi-layer substrate 210 is provided, wherein the multi-layer substrate 210 at least includes a metallic middle layer 215 and has a first surface 210a and a second surface 210b opposite to each other.

Next, as indicated in FIG. 2B, a first chip 220 is disposed on the first surface 210a such that the first chip 220 is electrically connected to the substrate 210. The first chip 220 can be electrically connected to the substrate 210 by wire bonding or flip-chip bonding. That is, a plurality of bonding wires 225 or a plurality of solder bumps (not shown) electrically connects to the first chip 220 and the substrate 210. However, the invention does not limit the ways of electrical connection between the first chip 220 and the substrate 210.

Then, as indicated in FIG. 2C, a first molding compound 230 is formed on the first surface 210a to cover the first chip 220.

After that, as indicated in FIG. 2D, a second chip 240 is disposed on the second surface 210b and is electrically connected to the substrate 210. Likewise, the second chip 240 can be electrically connected to the substrate 210 via by wire bonding or flip-chip bonding. That is, a plurality of bonding wires 245 or a plurality of solder bumps (not shown) electrically connects to the second chip 240 and the substrate 210. The invention does not limit the ways of electrical connection between the second chip 240 and the substrate 210. In addition, the first chip includes a base band chip and the second chip includes a radio frequency chip in one of embodiments. Alternatively, the first chip includes a radio frequency chip and the second chip includes a base band chip in other embodiments. The invention has no limitation thereto.

Next, as indicated in FIG. 2E, a number of solder bumps 250 are disposed on the second surface 210b of the substrate 210, and the solder bumps 250 are respectively electrically connected to the first chip 220 and the second chip 240 via the substrate 210, wherein it is preferable but not limiting that the solder bumps 250 are made of solder paste.

Then, as indicated in FIG. 2F, a molding compound 260 is formed on the second surface 210b to cover the second chip 240 and the solder bumps 250.

Afterwards, as indicated in FIG. 2G, the molding compound 260 is partly cut to form a second molding compound 260′ which covers the second chip 240. The present step is a half cut process for example. After the partly cut step, connection surfaces of 250′a of the solder bumps 250′ are exposed outside the second molding compound 260′. The second molding compound 260′ formed by partly cutting the molding compound 260 has at least one protruding portion 260′p whose position substantially corresponds to the second chip 240. It is noted that the solder bumps 250 originally have a first height (as shown in FIG. 2E and FIG. 2F). The half-cutting step removes not only a part of the molding compound 260, but also a part of the solder bumps 250, so that the connection surfaces 250′a of the solder bumps 250′ are electrically exposed as shown in FIG. 2G after half-cutting step.

Next, as indicated in FIG. 2H, an I/O frame board 270 is provided, wherein the frame board 270 has an opening 270h capable of accommodating the protruding portion 260′p. In one of embodiments, the opening 270h has a depth d larger than or equal to a thickness t of the protruding portion 260′p. In this step, the substrate 210 is disposed on the I/O frame board 270. The I/O frame board 270, such as a dual-layer substrate, is used for electrically connecting the solder bumps 250′ disposed on the substrate 210 to an external circuit. The substrate 210 is electrically connected to the I/O frame board 270 via the solder bumps 250′ with the second surface 210b facing downwards such that the I/O frame board 270 is electrically connected to the first chip 220 and the second chip 240 via the solder bumps 250′.

Then, as indicated in FIG. 2I˜FIG. 2J, the substrate 210 and the I/O frame board 270 are sawn to form a number of package structures for radio frequency modules 200. The package structure 200 formed in the sawing step includes an I/O block 270′. Thus, the package structure 200 can be electrically connected to an external circuit via the I/O block 270′.

In the present embodiment of the invention, the solder bumps 250′ are electrically connected to an external circuit via the I/O block 270′ (referring to FIG. 2J). Compared with the prior art which employs solder balls for electrical connection, the distance D between the solder bumps 250′ of the invention is smaller than that of the prior art and can be reduced to about 0.3 mm to 0.4 mm. According to an embodiment of the invention, it is preferable but not limiting that a ground layer of the multi-layer substrate 210 could be used as the metallic middle layer 215.

### <Package Structure for Radio Frequency Module>

Referring to FIG. 2J, a package structure for radio frequency module 200 according to the manufacturing method of the invention embodiment is shown. The package structure for radio frequency module 200 includes a multi-layer substrate 210, a first chip 220, a second chip 240, a number of solder bumps 250′, a first molding compound 230 and a second molding compound 260′. The first chip 220 and the second chip 240, for example, respectively are a base band element and a radio frequency element, which are respectively disposed on a first surface 210a and a second surface 210b of the multi-layer substrate 210. The multi-layer substrate 210 at least has a metallic middle layer 215 to achieve an electromagnetic shielding effect. The first molding compound 230 is disposed on the first surface 210a of the substrate 210 and covers the first chip 220. The solder bumps 250′ are disposed on the second surface 210b and are respectively electrically connected to the first chip 220 and the second chip 240 via the substrate 210. In the present embodiment of the invention, a molding compound 260 used for covering the second chip 240 and the solder bumps 250′ is partially cut to form a second molding compound 260′. The second molding compound 260′covers the second chip 240 and encircles sidewalls of the solder bumps 250′, and the connection surfaces 250′a of the solder bumps 250′ are exposed outside the second molding compound 260′.

In an embodiment of the invention, an I/O block 270′ is disposed on the second surface 210b and is electrically connected to the solder bumps 250′, such that the package structure 200 can be electrically connected to an external circuit (not illustrated) via the I/O block 270′. Hence, the package structure 200 has the advantage that the module can be easily customized. In another embodiment of the invention, the second molding compound 260′ formed by partly cutting has a protruding portion 260′p whose position substantially corresponds to the second chip 240. The I/O block 270′ has an opening 270h capable of accommodating the protruding portion 260′p of the second molding compound 260′. In one of embodiments, the opening 270h has a depth d larger than or equal to a thickness t of the protruding portion 260′p of the second molding compound 260′. In the present embodiment of the invention, the application of the I/O block 270′ will make the package structure 200 further thinned. Thus, the products using the package structure for radio frequency module 200 according to the embodiment of the invention are more competitive in the commercial market.

The package structure for radio frequency module disclosed in the above embodiments of the invention is advantaged in that the module is thinned and is easy to be customized. A base band element and a radio frequency element are respectively disposed on a first surface and a second surface of a multi-layer substrate. The multi-layer substrate has a metallic middle layer to achieve the electromagnetic shielding effect. Besides, the manufacturing method adopts a half cut process in the partly cut step, such that the connection surfaces of the solder bumps are exposed outside the second molding compound. Thus, the package structure can be electrically connected to the solder bumps via an I/O frame board and further electrically connected to an external circuit via the solder bumps. The package structure of the invention is advantaged in that the module is thinned and is easy to be customized, hence increasing the market value of the product.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing a package structure for radio frequency module, the method comprising:
providing a multi-layer substrate, and the substrate comprising a metallic middle layer, and having a first surface and a second surface opposite to each other;
disposing a first chip on the first surface, and the first chip electrically connected to the substrate;
forming a first molding compound on the first surface to cover the first chip;
disposing a second chip on the second surface, and the second chip electrically connected to the substrate;
disposing a plurality of solder bumps on the second surface, and the solder bumps respectively electrically connected to the first chip and the second chip via the substrate;
forming a molding compound on the second surface to cover the second chip and the solder bumps; and
cutting a part of the molding compound to form a second molding compound to cover the second chip, and connection surfaces of the solder bumps being exposed outside the second molding compound.

2. The manufacturing method according to claim 1, wherein the second molding compound formed in the partly cutting step has at least one protruding portion, the position of the protruding portion substantially corresponds to the second chip, and the manufacturing method further comprises:
providing an I/O frame board, wherein the I/O frame board has at least one opening capable of accommodating the at least one protruding portion of the second molding compound; and
disposing the substrate on the I/O frame board, wherein the I/O frame board is for electrically connecting the solder bumps of the substrate to an external circuit.

3. The manufacturing method according to claim 2, wherein in the step of providing the I/O frame board, the opening of the I/O frame board has a depth larger than or equal to a thickness of the protruding portion of the second molding compound.

4. The manufacturing method according to claim 2, wherein in the step of disposing the substrate on the I/O frame board, the second surface of the substrate faces downwards and the substrate is electrically connected to the I/O frame board by the solder bumps, such that the I/O frame board are electrically connected to the first chip and the second chip via the solder bumps.

5. The manufacturing method according to claim 1, wherein in the step of disposing the first chip, the first chip is electrically connected to the substrate by wire bonding or flip-chip bonding.

6. The manufacturing method according to claim 1, wherein in the step of disposing the first chip, the first chip includes a base band chip and the second chip includes a radio frequency chip.

7. The manufacturing method according to claim 1, wherein in the step of disposing the second chip, the second chip is electrically connected to the substrate by wire bonding or flip-chip bonding.

8. The manufacturing method according to claim 1, wherein in the step of disposing the second chip, the first chip includes a radio frequency chip and the second chip includes a base band chip.

9. The manufacturing method according to claim 1, wherein in the step of providing the substrate, the metallic middle layer is a ground layer.

10. The manufacturing method according to claim 1, wherein in the step of disposing the solder bumps, a distance between two adjacent solder bumps approximately ranges between 0.3 mm to 0.4 mm.

11. A package structure for radio frequency module, the package structure comprising:
a multi-layer substrate comprising a metallic middle layer, the substrate having a first surface and a second surface opposite to each other;
a first chip disposed on the first surface and electrically connected to the substrate;
a first molding compound disposed on the first surface to cover the first chip;
a second chip disposed on the second surface and electrically connected to the substrate;
a plurality of solder bumps disposed on the second surface and respectively electrically connected to the first chip and the second chip via the substrate; and
a second molding compound disposed on the second surface to cover the second chip, the second molding compound enclosing sidewalls of the solder bumps, so that connection surfaces of the solder bumps are exposed outside the second molding compound.

12. The package structure according to claim 11, wherein the second molding compound has at least one protruding portion whose position substantially corresponds to the second chip, and the package structure further comprises:
an I/O block having at least one opening capable of accommodating the at least one protruding portion of the second molding compound, the I/O block is positioned on the second surface, and on the periphery of the at least one protruding portion of the second molding compound, and is electrically connected to the solder bumps, and the package structure is electrically connected to an external circuit via the I/O block.

13. The package structure according to claim 12, wherein the I/O block has a thickness larger than or equal to a thickness of the protruding portion of the second molding compound.

14. The package structure according to claim 12, wherein the I/O block is a dual-layer substrate.

15. The package structure according to claim 11, further comprising:
a plurality of first bonding wires or a plurality of solder bumps electrically connected to the first chip and the substrate.

16. The package structure according to claim 11, wherein the first chip includes a base band chip and the second chip includes a radio frequency chip.

17. The package structure according to claim 11, further comprising:
a plurality of second bonding wires or a plurality of solder bumps electrically connected to the second chip and the substrate.

18. The package structure according to claim 11, wherein the first chip includes a radio frequency chip and the second chip includes a base band chip.

19. The package structure according to claim 11, wherein the metallic middle layer is a ground layer.

20. The package structure according to claim 11, wherein a distance between two adjacent solder bumps approximately ranges between 0.3 mm to 0.4 mm.
